(19) United States
(12) Patent Application Publication
(10) Pub. No.: US 2013/0154519 A1
(43) Pub. Date: Jun. 20, 2013

(54) LED LAMP WITH COLOR-MIXING CAVITY

(71) Applicant: SCOTT A. RIESEBOSCH, St. Catharines (CA)

(72) Inventor: SCOTT A. RIESEBOSCH, St. Catharines (CA)

(21) Appl. No.: 13/328,507

(22) Filed: Dec. 16, 2011

(51) Int. Cl. H05B 37/00; H01L 33/50

(52) U.S. Cl. 315/312; 257/91; 257/E33.06

(57) ABSTRACT

A device for emitting white light includes, in certain embodiments, an ultraviolet and/or a blue LED having an emission surface, a conversion coating spaced away from but enveloping the emission surface to form a first mixing cavity, at least one secondary LED emitting a color different from ultraviolet and blue and spaced away from the conversion coating, and a diffuser spaced away from but enveloping the conversion coating and the secondary LED to define a second mixing cavity that is unfilled.

### FIELD OF THE INVENTION

In various embodiments, the present invention relates generally to systems and methods incorporating light emitting diodes (LEDs), and more specifically to such systems and methods that produce white light.

### BACKGROUND

An increasing number of light fixtures utilize LEDs as light sources due to their lower energy consumption, smaller size, improved robustness, and longer operational lifetime relative to conventional filament-based light sources. Conventional LEDs emit light at a particular wavelength, ranging from, for example, red to blue or ultraviolet (UV) light. However, for purposes of general illumination, the monochromatic emitted light by LEDs must be converted to broad-spectrum white light.

Traditionally, there are two primary ways of obtaining white light from monochromatic LEDs. One approach is to combine individual LEDs that emit at different wavelengths, e.g., red, green, and blue, to form white light. The disadvantage of this approach is that it requires the use of multiple LEDs and thus increases overall cost and design complexity. Additionally, the different colors of light are often generated by different types of LEDs fabricated from different material systems. Combining different LED types may require costly fabrication techniques and complex control circuitry, since each LED may have different electrical requirements and behave differently under varied operating conditions (e.g., temperature or current) or over time. The other approach is to convert the blue or UV light emitted from the LEDs to white light by surrounding the LEDs with one or more fluorescent or phosphorescent materials, such as a phosphor, fluorescent dye, photo-luminescent semiconductor or quantum dots—herein referred to, collectively, as a phosphor. The phosphor converts a fraction of the blue or UV light from the shorter wavelengths to longer wavelengths, e.g., to a green or yellow light. The design and production of a light source using a monochrome emitter with phosphor conversion is simpler and less expensive than for a combination of LEDs; it is therefore a popular choice for making high-intensity white LED-based lamps. However, phosphor particles, in general, are randomly filled into the space surrounding the LED chips. This significantly reduces the uniformity of light and the efficiency of conversion. Additionally, the phosphor particles are usually too large to scatter light effectively in the phosphor-filled space. One solution to this problem is to surround the phosphor with a transparent encapsulant having scattering particles (e.g., titanium oxide, TiO₂) dispersed therein to effectively scatter light. However, traveling through a thick layer of a scattering encapsulant, in general, results in an intensity decrease of the light. Additionally, encapsulant materials add cost—a key consideration for devices intended for general illumination.

Consequently, there is a need for LED lamps that can emit white light with high uniformity and intensity but without high manufacturing costs.

### SUMMARY

In various embodiments, the present invention relates to systems and methods for generating white light with high uniformity and luminous intensity using monochromatic LEDs and two cavity spaces for uniformly mixing the light. Light emitted from one or more blue and/or UV LEDs travels through a first cavity space surrounded by a coating layer that converts a portion of the blue and/or UV light to longer wavelengths while allowing a portion of the blue and/or UV light to pass therethrough without conversion. One or more secondary LEDs, having an output color different from blue and UV light, is disposed in a second cavity space outside the conversion coating layer. Light emitted from the secondary LED(s), together with the unconverted blue and/or UV light as well as the converted, longer-wavelength light, mix in the second cavity to produce white light. The second cavity space is unfilled with any encapsulant materials, i.e., it contains air or another gas, or can be under vacuum. As a result, the output light emerging from the second cavity is undiminished in intensity by an encapsulant material. Increased intensity can be achieved by applying a reflective layer to the conversion coating in order to avoid loss of light into the first cavity; in some embodiments, the reflective material is preferentially reflective to the light produced by the secondary LED(s) relative to the light produced by the blue and/or UV LEDs. Furthermore, soft white light may be produced by surrounding the second cavity space with a diffuser.

Accordingly, in one aspect, the invention pertains to a white-light-emitting device. The device includes: (i) multiple ultraviolet or blue light-emitting diodes (LEDs) having at least one emission surface, (ii) a conversion coating spaced away from but enveloping the at least one emission surface to define a first mixing cavity therearound, the conversion coating converting a color of at least a portion of the light emitted by the multiple LEDs to a different color, (iii) at least one secondary LED, emitting light of a color different from ultraviolet and blue, spaced away from the first mixing cavity, and (iv) a diffuser spaced away from but enveloping the conversion coating and the secondary LED to define therearound a second mixing cavity that is unfilled, wherein mixing of the converted light and the light from the at least one secondary LED produces white light that is emitted through the diffuser. In one embodiment, the conversion coating includes at least one of a fluorescent material, a phosphorescent material, or quantum dots. The first and/or the second mixing cavity may be convex or dome-shaped.

In various embodiments, the white-light-emitting device further includes a reflective coating disposed on the conversion coating. The reflective coating may be more reflective of light emitted by the at least one secondary LED than light emitted by the conversion coating.

In some embodiments, the white-light-emitting device includes a controller for activating or deactivating selected ones of the LEDs to achieve a target value of a lighting parameter. The lighting parameter may be a luminous intensity and/or a color temperature.

In a second aspect, the invention relates to a white-light-emitting device. The device includes: (i) multiple ultraviolet or blue light-emitting diodes (LEDs) having at least one emission surface, (ii) a housing filled with a conversion material and enveloping the at least one emission surface, (iii) a reflective coating surrounding the conversion coating, (iv) at least one secondary LED, emitting light of a color different from ultraviolet and blue, spaced away from the conversion coating, and (v) a diffuser spaced away from but enveloping the conversion coating and the secondary LED to define therearound a second mixing cavity that is unfilled, wherein mixing of the converted light and the light from the at least one secondary LED produces white light that is emitted through the diffuser.

In a third aspect, the invention relates to a method for producing white light using LEDs. The method includes: (i) generating blue or UV light, (ii) converting the blue or UV light to light having a longer wavelength, (iii) generating light having a wavelength different from that of the blue, UV, and converted light, and (iv) mixing the light of steps (i), (ii), and (iii) in an unfilled spatial void to generate white light. In one implementation, the light of step (i) is generated in a first cavity and light of step (iii) is generated in a second cavity distinct from the first cavity, and further includes reflecting, from the first cavity, at least a portion of the light generated in step (iii).

As used herein, the term “substantially” means ±10% (e.g., by weight or by volume), and in some embodiments, ±5%. The term “consists essentially of” means excluding other materials that contribute to function, unless otherwise defined herein. Nonetheless, such other materials may be present, collectively or individually, in trace amounts.

Reference throughout this specification to “one example,” “an example,” “one embodiment,” or “an embodiment” means that a particular feature, structure, or characteristic described in connection with the example is included in at least one example of the present technology. Thus, the occurrences of the phrases “in one example,” “in an example,” “one embodiment,” or “an embodiment” in various places throughout this specification are not necessarily all referring to the same example. Furthermore, the particular features, structures, routines, steps, or characteristics may be combined in any suitable manner in one or more examples of the technology. The headings provided herein are for convenience only and are not intended to limit or interpret the scope or meaning of the claimed technology.

### BRIEF DESCRIPTION OF THE DRAWINGS

In the drawings, like reference characters generally refer to the same parts throughout the different views. Also, the drawings are not necessarily to scale, with an emphasis instead generally being placed upon illustrating the principles of the invention. In the following description, various embodiments of the present invention are described with reference to the following drawings, in which:

FIG. 1A is a cross-sectional elevation depicting a white LED device that includes first and second mixing cavities as described herein, where multiple blue and/or UV LEDs have a single emission surface.

FIG. 1B is a cross-sectional elevation depicting a white LED device similar to that shown in FIG. 1A, but in which at least some of the blue and/or UV LEDs have individual emission surfaces and some have a common emission surface.

FIG. 2 is a cross-sectional elevation of a device as shown in FIG. 1B and having a conversion material surrounding the blue and/or UV LEDs in the cavity in which they are disposed.

FIG. 3 schematically depicts a white LED device including power and control circuitry.

### DETAILED DESCRIPTION

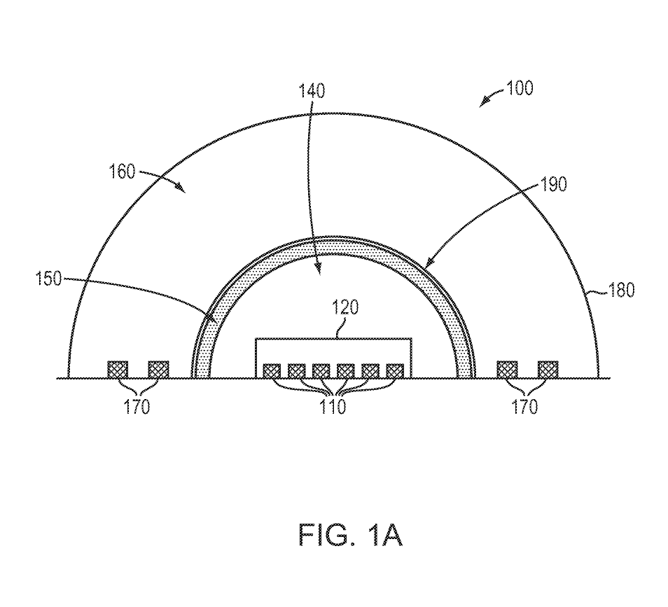

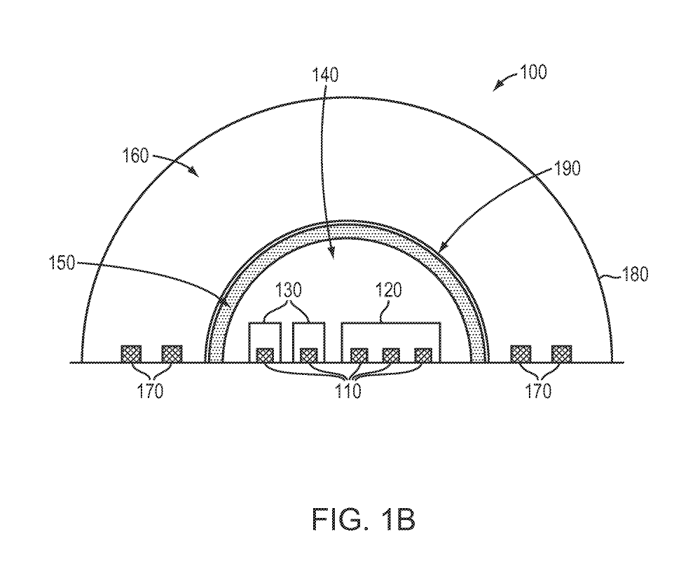

Refer first to FIG. 1A, which depicts an exemplary LED lamp 100 in accordance with embodiments of the present invention, although alternative systems with similar functionality are also within the scope of the invention. As depicted, the LED lamp 100 includes multiple blue and/or UV LEDs 110. LEDs 110 may be abut each other to form a single effective emission surface 120 or, alternatively, the LEDs may have individual emission surfaces 130; in some embodiments, some LEDs are grouped to have a common emission surface 120 and some LEDs have individual emissions surfaces 130, as depicted in FIG. 1B. Light emitted from emission surfaces 120 or 130 travels through the space of the surrounding cavity 140 and is incident upon a conversion layer 150, which comprises or consists essentially of a conversion material coated over or defining the outer surface of the cavity 140. The cavity 140 may be vacuum or filled with air or gas or an encapsulant material. The conversion layer 150 may have a convex or domed shape. In various embodiments, the conversion material on the coating layer 150 is a phosphor. The conversion material absorbs at least some of the light emitted from the LEDs 110 and re-emits at least some of the absorbed light in a spectrum containing one or more wavelengths that are longer than the blue and UV light. (For convenience, the term “color” is used herein to denote the monochromatic wavelength or wavelengths of light emitted by one or more LEDs.) For example, a Sr:thiogallate phosphor and ZnS may be used to convert UV light to green and blue light, respectively, and a (Gd, Y)₃(Al, Ga)₅O₁₂ phosphor is used to convert blue light to yellow light. If an encapsulant material fills the cavity 140, it preferably has an index of refraction substantially matching that of the emission surfaces 120 and/or 130 of the LEDs 110 in order to maximize light transmission through the cavity 140. Both converted and unconverted light emitted from the conversion coating 150 enter a second cavity 160 that surrounds the first cavity 140 and the conversion layer 150; the second cavity 160 may also have a convex or domed shape.

Light from the first cavity 140 can be made highly uniform by adjusting the phosphor thickness and concentration in the coating layer 150. Varying the thickness and concentration of the phosphor can also achieve a high degree of consistency in the converted color and its brightness. A series of LEDs 170, which emit light of a wavelength different from that of LEDs 110, are disposed within the second cavity 160. When an appropriate electrical signal is applied to the LED lamp 100, the LEDs 110, 170 emit light at their respective characteristic wavelengths. Light emitted from the conversion layer 150, including the converted light and light passing through without being converted, as well as light emitted from LEDs 170 are all well mixed in cavity space 160; the combination thereby provides white light with high uniformity. The second cavity 160 may be unfilled—as used herein, the term “unfilled” means vacuum or filled with air or other gas, but not with a solid material—reducing both light loss and cost relative to structures having cavities filled with a encapsulant material. LED lamps constructed in accordance herewith thus produce white light with high uniformity and intensity. In various embodiments, a diffuser 180 is coated on or defines the surface of the second cavity 160, providing soft white light. Light passing through the diffuser is spread out over a large solid angle; the LED lamp thus has equal luminance from all directions in the hemisphere surrounding the diffuser surface. This further contributes to the high uniformity of the emitted white light.

In some embodiments, a reflective coating 190 is applied to the outer surface of the conversion layer 150. The reflective coating 190 may exhibit high reflection over a range of wavelengths including the color emitted by LEDs 170, and low reflection over a range of wavelengths including the color emitted by LEDs 110. This avoids entrapment of light within the first cavity 140 while reducing the loss of light from LEDs 170 that would result from entry into cavity 140.

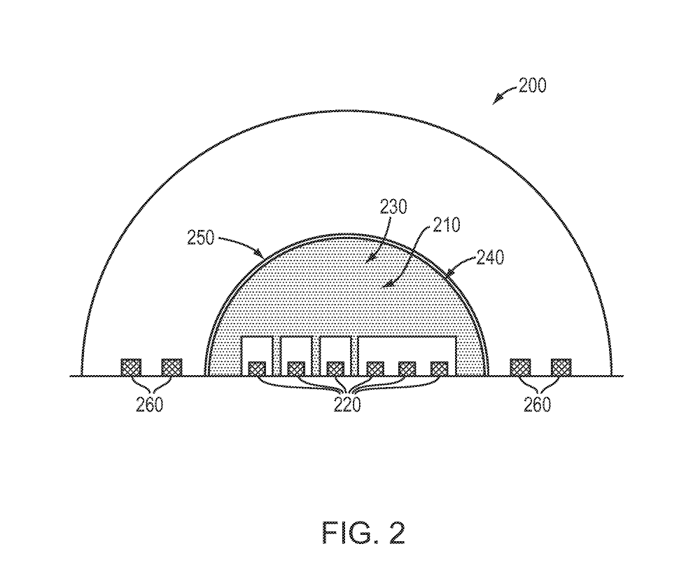

In some embodiments, as illustrated in FIG. 2, the conversion material 210 surrounds the blue and/or UV LEDs 220 and is dispersed throughout the cavity 230 that is defined or surrounded by a transparent wall 240. A reflective coating 250 may be applied to the wall 240 in order to eliminate loss of light from LEDs 260, thereby increasing the intensity of the LED lamp 200.

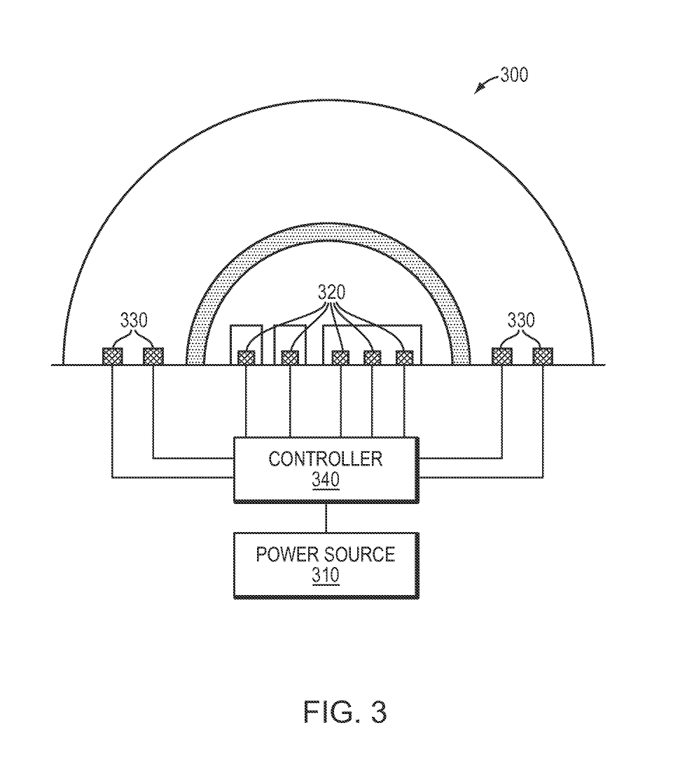

As depicted in FIG. 3, an LED lamp 300 in accordance herewith may include at least one power source 310 providing power to the blue and/or UV LEDs 320 and LEDs 330 via a suitable controller 340. In one embodiment, the controller 340 regulates the luminous intensity of the LED lamp 300 by activating an appropriate number of LEDs 320, 330. In another embodiment, the controller 340 produces different color temperatures of light by selectively activating and deactivating appropriate LEDs 320, 330. For example, the LED lamp may produce a warmer (i.e., lower color temperature) light by activating fewer blue and/or UV LEDs 320 and more of the LEDs 330 (e.g., red LEDs); whereas a cooler (i.e., higher color temperature) light can be achieved by activating more blue and/or UV LEDs 320 and fewer of the LEDs 330. In other embodiments, various ones of the LEDs 320, 330 emit at different wavelengths, permitting finer control over the final color temperature. The LED lamp 300 may thus be tailored to specific environments, ranging from a public area where warm light is preferable to promote relaxation to an office space where cool light is utilized to enhance concentration. The controller 340 may regulate the illumination and color temperature of the LED lamp 300 in response to commands by a user employing, for example, a wireless or wired remote-control device.

The controllers described herein may be implemented in software, hardware, or some combination thereof. For example, the system may be implemented on one or more server-class computers, such as a PC having a CPU board containing one or more processors. The controller may also include a main memory unit for storing programs and/or data relating to the activation or deactivation described above. The memory may include random access memory (RAM), read only memory (ROM), and/or FLASH memory residing on commonly available hardware such as one or more application specific integrated circuits (ASIC), field programmable gate arrays (FPGA), electrically erasable programmable read-only memories (EEPROM), programmable read-only memories (PROM), or programmable logic devices (PLD). In some embodiments, the programs may be provided using external RAM and/or ROM such as optical disks, magnetic disks, as well as other commonly used storage devices.

For embodiments in which the controller is provided as a software program, the program may be written in any one of a number of high level languages such as FORTRAN, PASCAL, JAVA, C, C++, C#, LISP, PERL, BASIC, PYTHON or any suitable programming language.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A white-light-emitting device comprising:
a plurality of ultraviolet or blue light-emitting diodes (LEDs) having at least one emission surface;
a conversion coating spaced away from but enveloping the at least one emission surface to define a first mixing cavity therearound, the conversion coating converting a color of at least a portion of the light emitted by the plurality of LEDs to a different color;
at least one secondary LED, emitting light of a color different from ultraviolet and blue, spaced away from the first mixing cavity; and
a diffuser spaced away from but enveloping the conversion coating and the secondary LED to define therearound a second mixing cavity that is unfilled, wherein mixing of the converted light and the light from the at least one secondary LED produces white light that is emitted through the diffuser.

2. The device of claim 1, further comprising a reflective coating disposed on the conversion coating.

3. The device of claim 2, wherein the reflective coating is more reflective of light emitted by the at least one secondary LED than light emitted by the conversion coating.

4. The device of claim 1, further comprising a controller for activating or deactivating selected ones of the LEDs to achieve a target value of a lighting parameter.

5. The device of claim 4, wherein the lighting parameter is a luminous intensity.

6. The device of claim 4, wherein the lighting parameter is a color temperature.

7. The device of claim 1, wherein the conversion coating comprises at least one of a fluorescent material, a phosphorescent material, or quantum dots.

8. The device of claim 1, wherein the first mixing cavity is convex or dome-shaped.

9. The white LED device of claim 1, wherein the second mixing cavity is convex or dome-shaped.

10. A white-light-emitting device comprising:
A plurality of ultraviolet or blue light-emitting diodes (LEDs) having at least one emission surface;
a housing filled with a conversion material and enveloping the at least one emission surface;
a reflective coating surrounding the conversion coating;
at least one secondary LED, emitting light of a color different from ultraviolet and blue, spaced away from the conversion coating; and
a diffuser spaced away from but enveloping the conversion coating and the secondary LED to define therearound a second mixing cavity that is unfilled, wherein mixing of the converted light and the light from the at least one secondary LED produces white light that is emitted through the diffuser.

11. A method for producing white light using LEDs, the method comprising:
(i) generating blue or UV light;
(ii) converting the blue or UV light to light having a longer wavelength;
(iii) generating light having a wavelength different from that of the blue, UV, and converted light; and
(iv) mixing the light of steps (i), (ii), and (iii) in an unfilled spatial void to generate white light.

12. The method of claim 12, wherein the light of step (i) is generated in a first cavity and light of step (iii) is generated in a second cavity distinct from the first cavity, and further comprising reflecting, from the first cavity, at least a portion of the light generated in step (iii).
